(19) United States
(12) Patent Application Publication
(10) Pub. No.: US 2011/0266233 A1
(43) Pub. Date: Nov. 3, 2011

(54) MOUNTING SYSTEM FOR SOLAR MODULES

(75) Inventors: Ralf Ritzler, Bielefeld (DE); Wadim Salzer, Bielefeld (DE); Andreas Rosenwirth, Enger (DE); Gerd Imkamp, Gutersloh (DE); Andre Stockhausen, Herford (DE); Carsten Hanke, Bielefeld (DE)

(73) Assignee: SCHUCO International KG, Bielefeld (DE)

(21) Appl. No.: 13/089,551

(22) Filed: Apr. 19, 2011

(30) Foreign Application Priority Data
Apr. 19, 2010 (DE) 20 2010 005 249.1

(51) Int. Cl. H01L 23/12

(52) U.S. Cl. 211/41.1

(57) ABSTRACT

Mounting system (1) for solar modules (6), having a substructure (7, 9, 11) on which a frame (2) is supported on which one or more plate-shaped solar modules (6) are held, and having an anchor (13, 35) that can be affixed to a building structure and supports the frame (2) in an upper region, wherein a retainer part (20, 50″) is provided at the anchor (13, 35) in order to fix the frame (2) and being adjustable to alter the inclination relative to the anchor (13, 35) by at least one axis.

The present invention relates to a mounting system for solar modules having a base part on which a frame is supported to which one or more plate-shaped solar modules are held, and an anchor capable of being attached to a wall of a building and which supports the frame in an upper region.

Mounting systems for solar modules are well known in which a frame is supported on a substructure, for example on pile-driven foundation posts. The frame is thereby mounted at a previously determined angle of pitch either on several of the posts forming the substructure, wherein short front posts are arranged to the south side and longer rear posts arranged to the north side, or on only one post, wherein the frame is supported approximately in the centre so that there is an even distribution of load. These mounting systems can be fixed atop or onto buildings, or onto outdoor open areas. A disadvantage is that, in addition to the frame, relatively complex and expensive substructures have to be provided.

Furthermore, solar module mounting systems integrated into the façades forming part of the building envelope are also well known. In such cases, in addition to the purely retaining function, the systems have to fulfil further obligations, like, for example, heat insulation and/or the provision of a waterproof façade or a waterproof section of the façade respectively. Disadvantageous here, however, is that retrofitting on the building envelope is no longer possible, or can be carried out only with considerable effort.

The object of the present invention, therefore, is to provide a mounting system for solar modules that is flexible enough to be adapted to various on-site conditions, and which makes an optimal alignment of the solar modules possible in the simplest of ways. In addition, retrofitting on buildings also has to be possible.

This object is achieved by means a mounting system with the features of claim 1.

According to the invention, a retainer is connected to the anchor for fixing the frame and which is adjustable to allow for an inclination adjustment relative to the anchor around at least one axis. Thus, the alignment of the solar modules can be adapted to the on-site conditions. In addition, the pitch adjustment can be used to optimise the angle of the solar modules depending on the prevailing season. For example, in winter a steeper positioning of the solar modules than in summer can be applied in order to increase the degree of efficiency. In doing so, the adjustment does not have to take place exactly around an axis, but can also be achieved by a swivel movement or by superimposed push and rotate motions.

According to a preferred embodiment refinement, the retainer relative to the anchor is adjustable around a horizontal axis. Thereby, the solar modules can be inclined to the horizontal position, which, on the one hand, makes an alignment depending on the season possible, and, on the other hand, enables positioning even in the case of unevenness. According to the season, the preferred angle of inclination to the horizontal lies in a range between 50° and 80°, depending on the location of the mounting system.

Alternatively or additionally, the retainer relative to the anchor is adjustable around an essentially vertical axis. This makes it possible to position the solar modules relative to a building or a building structure. Thus, in case the wall of the building is not laid out to face either south or north, a flexible adaptation can be carried out by an adjustment around an essentially vertical axis. The vertical axis can thereby be constructed according to the angle of pitch of the profiles being erected, so that the “vertical axis” is formed by the longitudinal axis of the profiles of the frame and inasmuch can deviate slightly from the vertical.

Preferably, the retainer relative to the anchor is adjustable around several axes, thereby resulting in a particularly flexible adaptation to the on-site conditions without the mounting system having to be altered.

The plate-shaped solar modules thereby span a plane that is preferentially arranged at a surface of a wall of a building and tilted both in a horizontal direction as well as in a vertical direction. In many cases, the wall of a building on which solar modules are to be mounted does not extend in an east-west direction, making it necessary to adjust the alignment of the solar modules relative to the wall of the building in order to attain an optimal degree of efficiency. This can be carried out by way of appropriate inclination adjustment around both axes.

The base part is preferably swivel-mounted to a socket around a horizontal axis, for example, by means of a hinge joint. Furthermore, the length of the anchor can be modified in order to adjust the span between the retainer and the wall, so that an inclination adjustment around a horizontal axis can be easily done. This allows for easy retrofitting on existing buildings such as industrial premises.

According to a further embodiment refinement, an upwardly extending profile is attached to the retainer part and is longitudinally slidably adjustable relative to the retainer part. Thus, for installation purposes, the retainer part can be simply pushed onto the profile. In addition, thermal stress can be avoided, which can occur when the frame with a long profile is installed, for example in order to install a frame with a height of more than 5 m. To allow for slidable positioning, the retainer part can thereby partially clasp a section of the profile, or, by employing other means of guidance, make a slidable movement of the profile possible.

The invention will be described subsequently in more detail by means of embodiments in conjunction with the accompanying drawings, wherein:

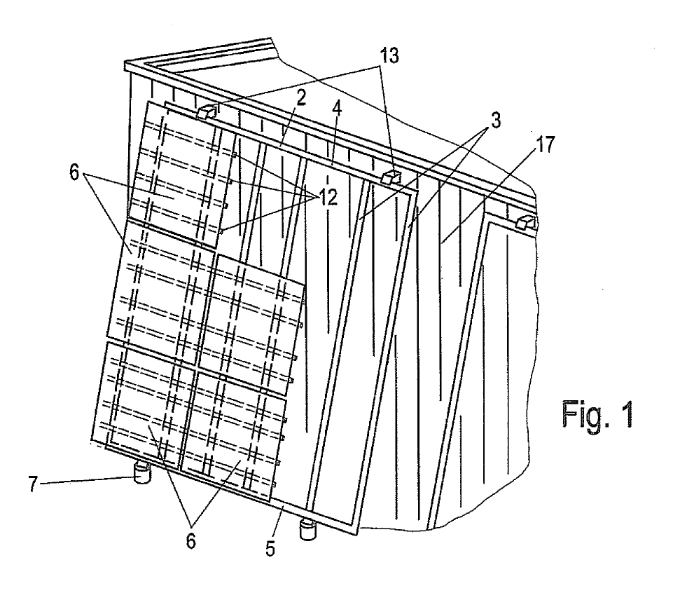

FIG. 1 shows a perspective view of an embodiment of a mounting system according to the invention;

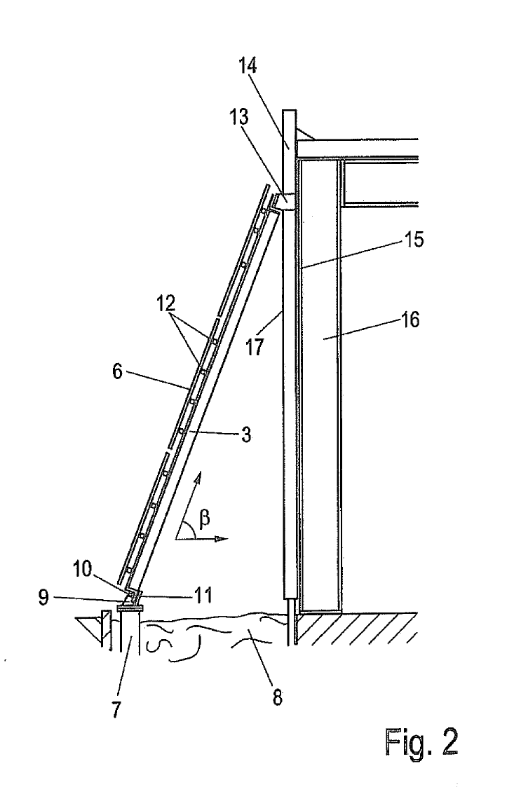

FIG. 2 shows a side view of the mounting system of FIG. 1;

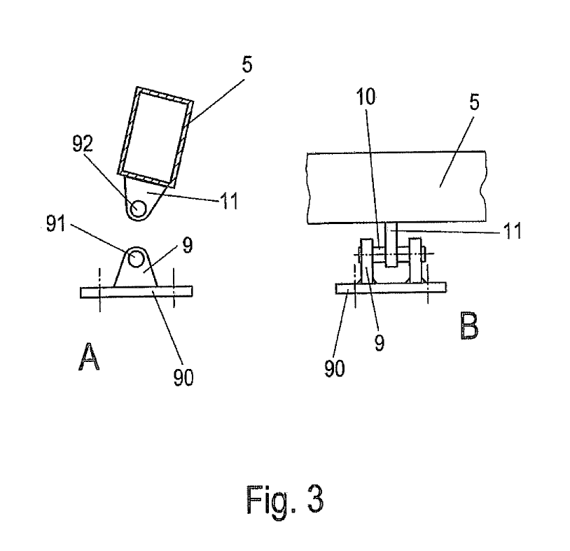

FIGS. 3A and 3B show two views of the base part of the mounting system of FIG. 1;

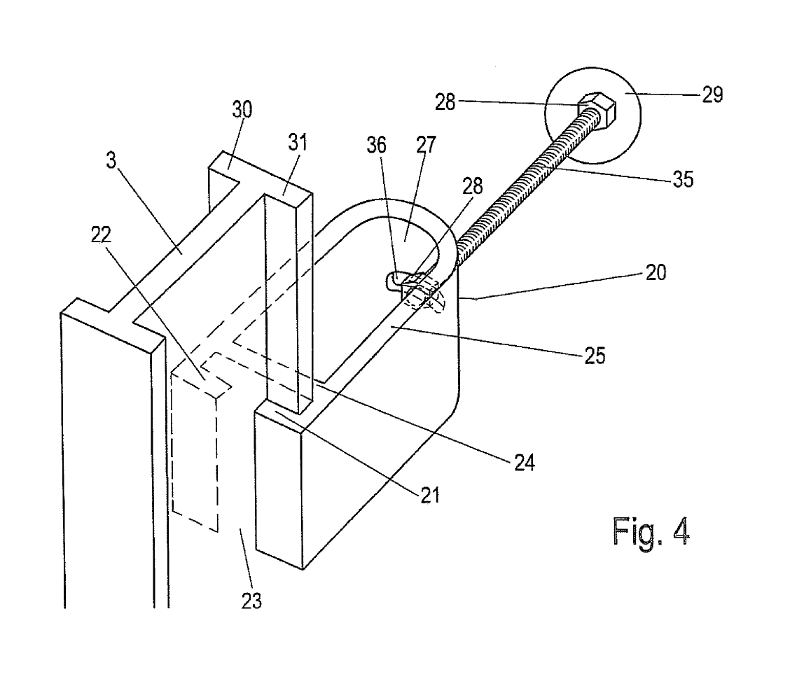

FIG. 4 shows a perspective view of a retainer part of the mounting system of FIG. 1;

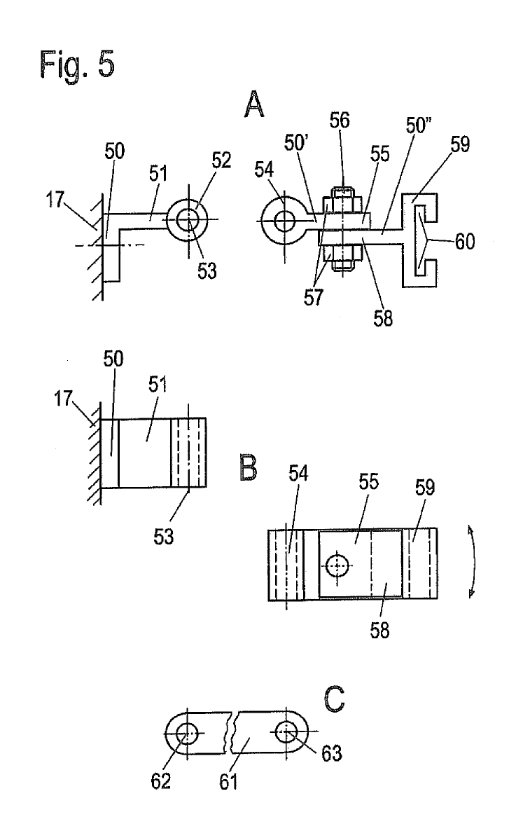

FIGS. 5A to 5C show several views of a modified refinement of a retainer for a mounting system of FIG. 1;

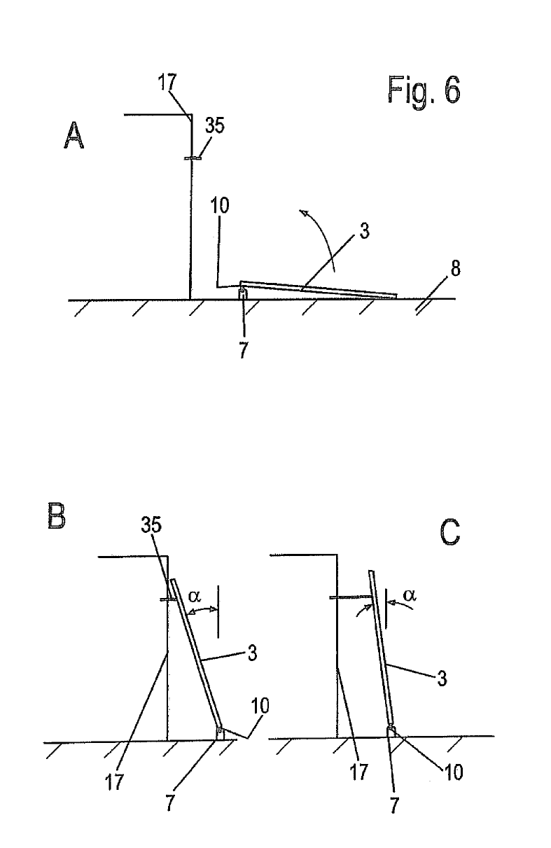

FIGS. 6A to 6C show several views of the mounting system of FIG. 1 during installation;

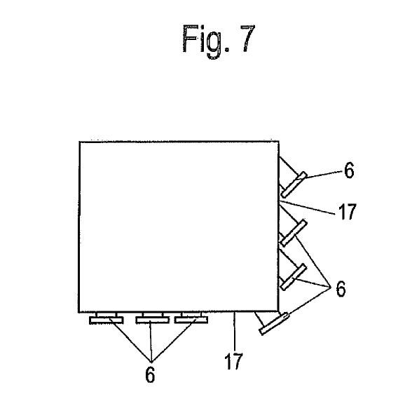

FIG. 7 shows an overhead view of a building with several solar modules;

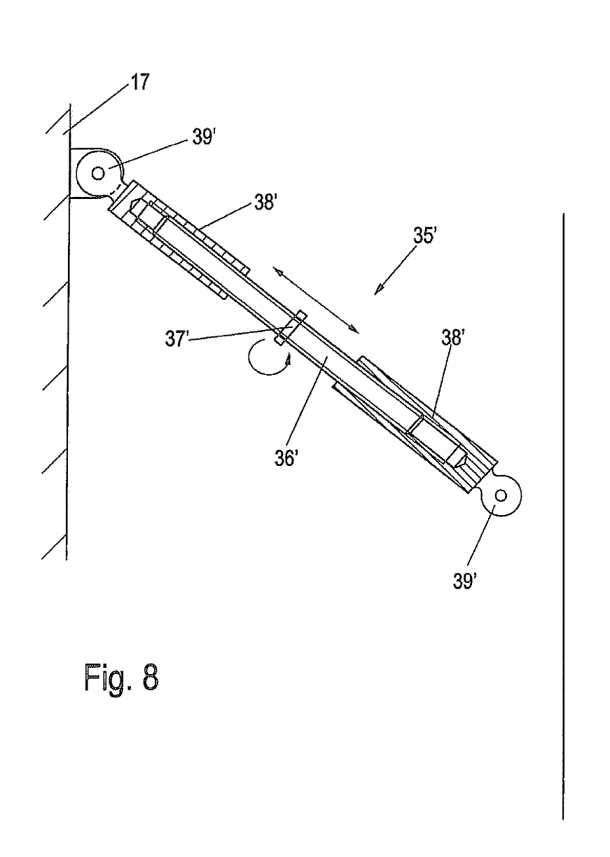

FIG. 8 shows a detailed view of a lengthwise adjustable anchor for a mounting system according to the invention, and

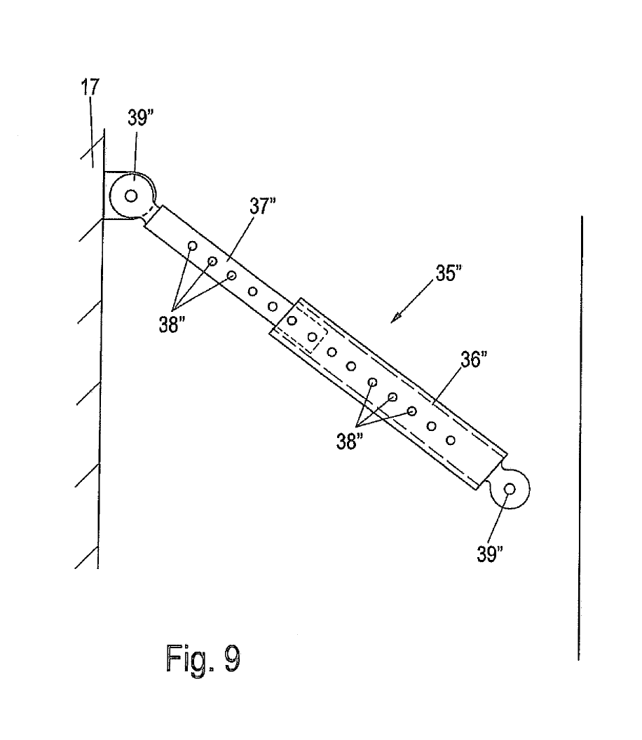

FIG. 9 shows a view of a modified anchor having lengthwise adjustability.

A mounting system 1 for solar modules comprises a frame 2 consisting of upwardly extending profiles 3 and horizontal profiles 4 and 5, wherein in FIG. 1 only an upper horizontal profile 4 and a lower horizontal profile 5 are shown. Further horizontal profiles can be arranged in the middle section. One or more solar modules 6 are attached to the frame 2 and held to the frame 2 by means of strip-shaped fixing devices 12.

The frame 2 is supported at the bottom by a substructure that bears almost completely the weight load of the frame 2 with the solar modules 6. The substructure comprises a base part 11 and a stationary part 9, which is attached to a pile-driven foundation post 7 that is anchored in the ground 8 (FIG. 2).

The frame 2 is, in its upper region at certain points that are disposed to each other at intervals, attached to a wall 17 or the façade of a building respectively by means of anchors 13. The frame 2 can also be extended over greater heights, for example over 4 m, and can be installed on the walls of industrial premises. In order to obtain an optimal angle of pitch β corresponding to the on-site conditions, the base part 11 is disposed at a distance from the wall 17 of the building, wherein the angle of pitch can lie, for example, within a range of between 60° and 80°. The wall 17 of the building comprises an insulation 14 that is arranged adjacent to an interior wall 15. A post 16 is arranged in the interior area, which is necessary for structural purposes and to which an anchor 13 can be attached. It is possible to include a counter bearing for the anchor 13 in the interior area.

FIGS. 3A and 3B depict a base part 11 that is formed as a lug and welded to the bottom of a cross member 5. The base part 11 includes an opening 92 through which the one axis 10 can be inserted. To facilitate pivotable positioning of the base part 11, a stationary part 9 is provided formed out of two lugs also having an opening 91 to allow for the insertion of the axis 10. The two lugs are joined to each by means of a mounting plate 90 and are welded there. The mounting plate 90 can be fixed to a base made of concrete, for example, or to a post.

FIG. 4 depicts the mounting for a post 3 rising at an angle of pitch β and which is designed as a double-T-profile having accordingly at each opposing end two laterally protruding webs 30 and 31 that are connected to each other by a central web 32. The profile 3 is slidably positioned by means of a retainer 20, which is designed in a U-shape and has two brackets 25 and 26 that are connected to each other by a bottom side 27. An anchor 35 designed as a threaded rod is arranged on the bottom side 27 and attached to a post 16 of the building or to another structural element of the building. At a duct in a wall, a seal 29 is attached by means of a nut 28 to the anchor 35. Likewise, the retainer 20 is fixed in the desired position by means of nuts 28. In order to slidably position the profile 3, inwardly directed webs 21 and 22 as well as a connecting web 24 are designed to clasp the webs 30 and 31 of profile 3. The central web 32 is guided through a slit 23 between the webs 21 and 22. Thus, the profile 3 can be moved in a longitudinal direction whilst still being held by the retainer 20.

In the depicted embodiment in FIG. 4, the bottom side 27 is designed in a rounded form and, appropriately, the slot 36 is curved as well. Thus, the retainer part 20 can be pivoted relative to the anchor 35 in order to align the profile 3 and consequently the frame 2 with the solar modules 6. In so doing, the swivel axis runs perpendicular to the longitudinal axis of the bar-shaped anchor 35. In addition, by means of appropriate inclined washers under the nuts 28, it is possible to achieve a certain adjustment around an axis perpendicular to the slot 36.

FIGS. 5A to 5C show a further design refinement of a multi-part retainer element used to fix a frame 2 to a wall 17 of a building. A first anchor part 50 is attached to a schematically depicted wall 17 and includes a protruding section 51 to which a sleeve 52 is arranged to form a rotational axis 53. A second sleeve 54 of a second anchor part 50′ is attached to the sleeve 52 by means of a not shown axis wherein the second anchor part 50′ includes a sleeve 55 at the opposite side and through which an axis 56 extends. Fixed to the axis 56 is a sleeve 58 of a third anchor part 50″ and through which the axis 56 also extends, wherein the second anchor part 50′ and the third anchor part 50″ are secured to each other on the axis 56 by means of nuts 57. On the third anchor part 50″, a guidance element 59 is arranged with grooves 60 to allow for the introduction of a section of a profile 3. The third anchor part 50″ forms inasmuch a retainer part for the slidable positioning of the profile 3.

The attachment of the sleeves 52 and 54 can be carried out as with the sleeves 55 and 58, so that the third anchor part 50″ is positioned to pivot about both a horizontal axis as well as a vertical axis at the first anchor part 50.

In addition, an extension element 61 can be fitted between the sleeve 52 and the sleeve 54 and which features openings 62 and 63 at the opposing ends into which the appropriate axes can be inserted.

FIGS. 6A to 6C schematically depict the installation of a mounting system according to the invention. FIG. 6A depicts at the bottom side a pile-driven foundation post 7 mounted into the ground 8 and to which a stationary part 9 of the ground part is attached. Attached to a swivel-mounted retainer part 11 positioned to pivot about an axis 10, is a profile 3 that lies on the ground and whilst on the ground can be connected to additional profiles 3 by means of horizontal profiles 4 and 5 to form a frame 2. The frame 2 can then be brought into an intermediate position disposed from the ground in order to mount the solar modules. Furthermore, the necessary anchors 35 are attached to a wall 17 of the building.

Subsequently, the posts 3 are swung up into position, either separately or together with the frame 2 as wished. Afterwards, a retainer part 20, 20′ or the third anchor part 59′ is slid onto the profile 3 and attached to the anchor 35. In the process, profile 3 and therefore also the solar modules 6 are brought into an angled position α relative to the vertical. The angle of pitch α can be chosen to be somewhat greater or smaller depending on the prevailing season, preferably between 10° and 30°.

FIG. 7 schematically depicts a building with several solar modules 6 mounted on a mounting system according to the invention. As the frame 2 is positioned to pivot about the base part, the angle of pitch a can be adjusted. Furthermore, it is also possible to align the solar panels at an angle to the surface of a wall 17 of the building, as shown on the right side of the drawing. To this end, for example, a multi-part anchor 50, 50′ and 50″is used that allows for an appropriate optimal alignment when attaching the solar modules 6.

FIG. 8 schematically depicts a longitudinally slidable anchor 35′ having a rod-shaped threaded portion 36′ provided with a centrally placed tool attachment section 37′ and screwed at the opposing ends into a sleeve 38′. A connection point 39′ is provided at the sleeve 38′ in order to be able to connect the anchor 35′ to a wall 17 of a building or respectively to a retainer 20, 20′ or 40. By changing the length of the anchor 35′, the angle of inclination of the solar modules can be adjusted.

FIG. 9 depicts a modified design refinement of an anchor 35″, which likewise is longitudinally adjustable. To this end, a bar 37″ engages with a sleeve 36″ wherein both in the bar as well as in the sleeve 36″ openings 38″ have been formed through which appropriate pins can be inserted for fastening purposes. A point of attachment 39″ is arranged on the bar 37″ to enable the connection to a wall 17, and, equally, there is a point of attachment 39″ on the sleeve 36″ to enable a connection to a retainer part 20.

In the depicted embodiments, the retainer parts 20, 20′, 59 are each mounted on a profile 3 that is slidably positioned. It is, of course, also possible to mount additional components to the frame 2 to allow for slidable positioning relative to a stationary anchor.

1. Mounting system for solar modules (6), having a substructure (7, 9, 11) on which a frame (2) is supported on which one or more plate-shaped solar modules (6) are held, and having an anchor (13, 35) that can be affixed to a building and supports the frame (2) in an upper region, characterized in that a retainer part (20, 50″) is provided at the anchor (13, 35) to fix the frame (2) and being adjustable to alter the inclination relative to the anchor (13, 35) by at least one axis.

2. Mounting system according to claim 1, characterized in that the retainer part (20, 50″) relative to the anchor (13, 35) is adjustable around a horizontal axis.

3. Mounting system according to claim 1 or 2, characterized in that the retainer part (20, 50″) relative to the anchor (13, 35) is adjustable around an essentially vertical axis.

4. Mounting system according to any one of claims 1 to 3, characterized in that the retainer part (20, 50″) relative to the anchor (13, 35) is adjustable around several axes.

5. Mounting system according to any one of claims 1 to 4, characterized in that the length of the anchor (13, 35) can be modified in order to adjust the distance between the retainer part (20, 50″) and the wall (17).

6. Mounting system according to any one of claims 1 to 5, characterized in that the plate-shaped solar modules (6) span a plane that is arranged at a wall (17) of a building and tilted both in a horizontal direction as well as in a vertical direction.

7. Mounting system according to any one of claims 1 to 6, characterized in that the base part (11) is swivel-mounted to a socket part (9) about a horizontal axis.

8. Mounting system according to any one of claims 1 to 7, characterized in that an upwardly extending profile (3) being longitudinally relative to the retainer part (20, 50″) slidably adjustable is attached to the retainer part (20, 50″).

9. Mounting system according to claims 8, characterized in that the retainer part (20, 50″) partially clasps a section of the profile (3).
